(19) United States
(12) Patent Application Publication
(10) Pub. No.: US 2024/0248959 A1
(43) Pub. Date: Jul. 25, 2024

(54) DEVICE AND METHOD FOR WAFER MAP PATTERN DETECTION USING HIERARCHICAL CLUSTERING

(71) Applicant: KOREA UNIVERSITY RESEARCH AND BUSINESS FOUNDATION, Seoul (KR)

(72) Inventors: Yoonsuh JUNG, Seoul (KR); Joowon JEONG, Seongnam-si (KR)

(21) Appl. No.: 18/402,839

(22) Filed: Jan. 3, 2024

(30) Foreign Application Priority Data
Jan. 3, 2023 (KR) 10-2023-0000910
Nov. 30, 2023 (KR) 10-2023-0170803

(51) Int. Cl. G06F 18/231; G06N 20/00; G06T 7/00

(52) U.S. Cl. CPC G06F 18/231; G06N 20/00; G06T 7/0004; G06T 2207/20081; G06T 2207/30148

(57) ABSTRACT

Disclosed is a method for semiconductor wafer pattern detection and classification using hierarchical clustering (HC). The method for semiconductor wafer pattern detection and classification is performed by a computing device including at least a processor and includes acquiring raw data; detecting a failure pattern of a target semiconductor wafer; and classifying the failure pattern of the target semiconductor wafer, and the detecting of the failure pattern includes removing a cluster that does not satisfy a first tuning parameter through the hierarchical clustering (HC); and determining that the target semiconductor wafer is normal when the cluster that satisfies the first tuning parameter is absent. The classifying of the pattern includes isolating a wafer previously identified to be defective into single patterns that satisfy a second tuning parameter, extracting a feature, and classifying the pattern through supervised learning.

### CROSS-REFERENCE TO RELATED APPLICATION

The present application claims the benefit of priority to Korean Patent Application No. 10-2023-0000910 filed on Jan. 3, 2023 and Korean Patent Application No. 10-2023-0170803 filed on Nov. 30, 2023 in the Korean Intellectual Property Office. The aforementioned applications are hereby incorporated by reference in their entireties.

### TECHNICAL FIELD

The present invention relates to technology for detecting and classifying a defect of a semiconductor wafer using machine learning, and more particularly, to a device and method for detecting and classifying a defect in a semiconductor wafer using hierarchical clustering.

### RELATED ART

A semiconductor manufacturing process includes a plurality of chemical processes to construct a circuit and is made up of circular wafer units that may generate hundreds to tens of thousands of semiconductor chips. The number of normal chips that are ultimately produced, that is, yield is a very important factor in semiconductor manufacturing that is a complex and long multi-stage chemical process. Therefore, if it is possible to early detect a defect and to identify a cause of the defect and then take an action through failure pattern classification, it is possible to minimize a yield loss caused by failure in a process.

Failure detection and classification utilizes quality test results immediately after processing each semiconductor process stage. The results are displayed in a form of defective and normal at a location of each chip on a circular wafer and such results are called a wafer bin map (WBM). A spatial failure pattern may be visually verified and, through this, presence and absence of failure and a type of failure may be determined, which allows the cause in the process to be inferred.

FIG. 1 illustrates examples of a failure pattern on a wafer, including a center failure, donut failure, local failure, edge local failure, edge ring failure, random failure, and scratch failure.

In the existing research, a method most frequently used for wafer failure detection includes spatial filtering, such as de-noising, and a spatial randomness test.

Spatial filtering refers to an image processing method and removes noise through smoothing. Spatial filtering is a method of performing detection by acquiring a threshold that distinguishes a systematic pattern and an unsystematic pattern for an average and a median calculated by adding a weighted sum to the number of defects present around a point in a two-dimensional (2D) space and exhibits excellent performance in most cases. However, when a scratch-shaped pattern, such as a thin and long straight line or a round line, is present in a wafer with a lot of noise, there is a limitation in detecting a systematic pattern. An average filter and a median filer are commonly used.

Another method is the spatial randomness test. Similar to spatial filtering, the spatial randomness test is a method of testing hypothesis by counting the number of surrounding points (joint-count statistics) and using a log odds ratio or chi-square statistic thereof.

Once a wafer is determined to be defective, failure pattern classification is required to find the root cause in a process. Supervised learning corresponds to a process from de-noising to classification. For determination that a systematic failure is present, (1) perform de-noising to leave only systematic failure patterns in a wafer, (2) if a plurality of failure patterns is present in a single wafer, separate each into a single pattern, (3) extract feature of each failure pattern, and (4) classify the pattern through supervised learning. The cause of failure in a manufacturing process may be found using the classified pattern.

In the case of using unsupervised learning, a failure pattern may be known in a form in which wafers with similar patterns are clustered after de-nosing. Unlike supervised learning, there is an advantage in classifying a pattern with an unknown failure pattern.

Through hierarchical clustering (HC) with alleviated burden in calculating the number of clusters, the present invention first detects a defect in a wafer and second attempts pattern classification by combining features acquired through defect separation with a random forest that is a classifier that does not require a variable selection. Through this, the cause of a problem in a process may be early identified and an action may be taken.

### DETAILED DESCRIPTION

### Subject

A technical subject to be achieved by the present invention is to provide a device and a method for semiconductor wafer pattern detection and/or classification using hierarchical clustering (HC).

### Solution

A method for semiconductor wafer pattern detection and classification using hierarchical clustering (HC) according to an example embodiment of the present invention is performed by a computing device including at least a processor and includes acquiring raw data; detecting a failure pattern of a target semiconductor wafer; and classifying the failure pattern of the target semiconductor wafer, and the detecting of the failure pattern includes removing a cluster that does not satisfy a first tuning parameter through the hierarchical clustering (HC); and determining that the target semiconductor wafer is normal when the cluster that satisfies the first tuning parameter is absent.

### Effect

A device and method for semiconductor wafer pattern detection and/or classification according to an example embodiment of the present invention may more quickly and accurately detect and/or classify a large amount of data.

In particular, in the case of pattern detection, although only a small number of defective samples (e.g., 5 or less for each pattern) are secured, failure detection may be automated if there are a sufficient number of (e.g., about 100) normal samples. Even when a new pattern occurs, a failure pattern may be detected.

### BRIEF DESCRIPTION OF DRAWINGS

FIG. 1 illustrates examples of a failure pattern on a wafer, including center failure, donut failure, local failure, edge local failure, edge ring failure, random failure, scratch failure, and none.

FIG. 2 is a schematic flowchart illustrating a method proposed in the present invention.

FIG. 3 is a flowchart illustrating a pattern detection method of a semiconductor wafer using hierarchical clustering according to an example embodiment of the present invention.

### BEST MODE

Disclosed hereinafter are exemplary embodiments of the present invention. Particular structural or functional descriptions provided for the embodiments hereafter are intended merely to describe embodiments according to the concept of the present invention. The embodiments are not limited as to a particular embodiment.

Terms such as “first” and “second” may be used to describe various parts or elements, but the parts or elements should not be limited by the terms. The terms may be used to distinguish one element from another element. For instance, a first element may be designated as a second element, and vice versa, while not departing from the extent of rights according to the concepts of the present invention.

Unless otherwise clearly stated, when one element is described, for example, as being “connected” or “coupled” to another element, the elements should be construed as being directly or indirectly linked (i.e., there may be an intermediate element between the elements). Similar interpretation should apply to such relational terms as “between”, “neighboring,” and “adjacent to.”

Terms used herein are used to describe a particular exemplary embodiment and should not be intended to limit the present invention. Unless otherwise clearly stated, a singular term denotes and includes a plurality. Terms such as “including” and “having” also should not limit the present invention to the features, numbers, steps, operations, subparts and elements, and combinations thereof, as described; others may exist, be added or modified. Existence and addition as to one or more of features, numbers, steps, etc. should not be precluded.

Unless otherwise clearly stated, all of the terms used herein, including scientific or technical terms, have meanings which are ordinarily understood by a person skilled in the art. Terms, which are found and defined in an ordinary dictionary, should be interpreted in accordance with their usage in the art. Unless otherwise clearly defined herein, the terms are not interpreted in an ideal or overly formal manner.

Example embodiments of the present invention are described with reference to the accompanying drawings. However, the scope of the claims is not limited to or restricted by the example embodiments. Like reference numerals proposed in the respective drawings refer to like elements.

Hereinafter, semiconductor wafer data (WM-811K) is introduced.

Data used in experiments is real data (WM-811K) released by Taiwanese semiconductor manufacturing company (Wu M J, Jang J S R, and Chen J L (2015). Wafer map failure pattern recognition and similarity ranking for large-scale data sets. IEEE Transactions on Semiconductor Manufacturing, 28(1), 1-12.) and there are a total of 811,457 wafer bin maps (WBMs). Among them, 172,950 wafer bin maps (WBMs) include a normal status or a name of a failure pattern written one for each wafer. Inside a circular wafer, a die that is a space for a single semiconductor chip is divided into a grid and a WBM may be categorized by wafer and die size. Wafers have various sizes and hundreds to thousands of wafers are included in the same size.

On a single wafer, test results of multiple observations are displayed in a discrete form. The number of observations ranges from 45 to 28,000 per wafer, with an average of 2,000. Semiconductor manufacturing goes through a multi-stage process and tests are conducted for each process. If test results of observations show a certain systematic pattern in a geographic space on a wafer, it may be called a failure pattern.

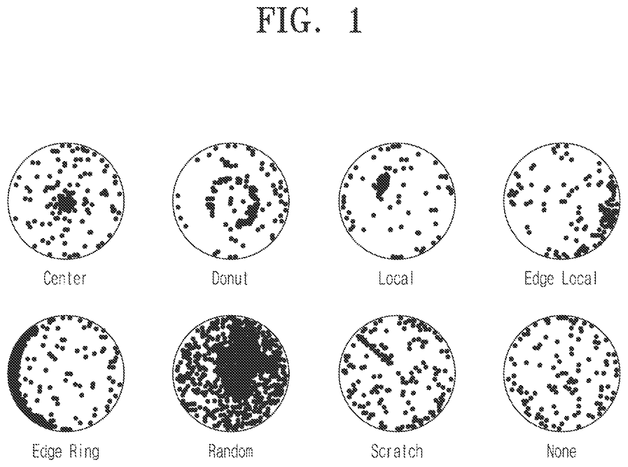

As shown in FIG. 1, failure patterns of a wafer included in data includes center failure, donut failure, local failure, edge local failure, edge ring failure, random failure, scratch failure, and the like. A causative process differs depending on each failure pattern. For example, the center failure that is a circular pattern in the center occurs due to a change in uniformity that occurs during chemical-mechanical planarization. The edge ring failure that is a round pattern of wafer edge occurs due to an etching problem or mismatch between layers in a storage node process. As a result, due to smaller contact holes, write recovery time failure occurs and the edge ring failure occurs accordingly. The scratch failure occurs due to improper transport or agglomerated particles and mainly occurs due to hardening of a pad during a chemical-mechanical planarization process. The local failure that is a failure pattern in a specific area of a wafer mainly occurs due to a change in uniformity or an uneven cleaning work. The edge local failure that is a failure pattern in a specific area of the wafer edge may usually occur during a thin film deposition process.

Since WM-811K includes various wafer sizes and die sizes, the same size of wafers and dies and a die size that has an even failure pattern and includes a significant amount of normal wafers may be selected. In 1376 die size, 44×41 wafer size may be targeted and a pattern with few samples (e.g., a near full pattern with only 1 sample) may be excluded. The selected data includes 6,133 wafers and, among them, 90.23% are normal. Ratios for the respective failure patterns used for analysis herein are shown in Table 1.

TABLE 1

| Failure pattern type | Count (%) | |
|---|---|---|
| none | 5,534 | (90.23%) |
| center | 18 | (0.29%) |
| donut | 12 | (0.2%) |
| edgeloc | 390 | (6.36%) |
| edgering | 17 | (0.28%) |
| loc | 101 | (1.65%) |
| random | 13 | (0.21%) |
| scratch | 48 | (0.78%) |
| total | 6,133 | (100%) |

Hereinafter, wafer map failure pattern detection and failure pattern classification methodology will be described.

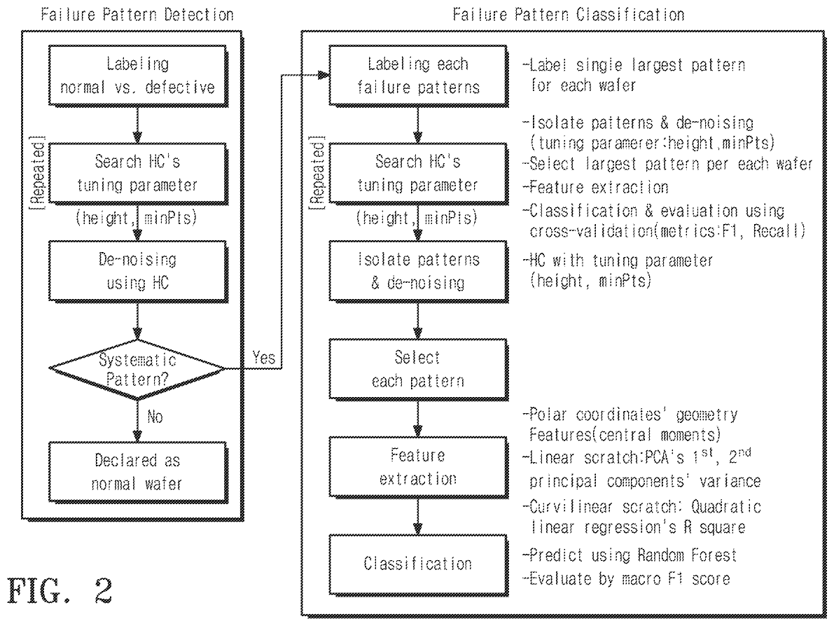

A first stage of wafer failure pattern detection and failure pattern classification is to distinguish a defective wafer with a systematic pattern from a normal pattern without the systematic pattern. Then, a type of failure may be verified only with respect to defective wafers. An approximate flowchart illustrating a method proposed in the present invention is illustrated in FIG. 2.

### 1. Failure Pattern Detection

The present invention proposes a noise processing method using hierarchical clustering based on the fact that an individual not belonging to a cluster is processed as noise in an example of using DBSCAN of Jin et al. (Jin C, Na H, Piao M, Pok G, and Ryu K (2019). A novel dbscan-based defect pattern detection and classification framework for wafer bin map. IEEE Transactions on Semiconductor Manufacturing, 32(3), 286-292.) and exploits the proposed method for wafer failure detection.

There are several methods for calculating and linking a distance between clusters. As a result of experimentally using options provided from R's hclust function, Minkowski distance

$$D ( X , Y ) = {( {\sum }_{i = 1}^{n} {\vert {x}_{i} - {y}_{i} \vert}^{p} )}^{1 / p}$$

and a shortest linkage method (single linkage) may be used, which experimentally show the best performance. Distance calculation methods tried in the experiments include Manhattan distance, Euclidean distance, Minkowski, and Canberra distance, and tried linkage methods include complete linkage, single linkage, Ward's method, and average linkage. Minkowski distance uses p=3, which shows the best performance and this value may be finally selected. However, the scope of the present invention is not limited thereto and different calculation methods and/or linkage methods may be used depending on example embodiments.

By applying the aforementioned method to training data, a tuning parameter value required for a hierarchical clustering model is selected. This tuning parameter represents a height to be cut on a dendrogram after clustering and the minimum number of individuals to be recognized as a cluster, which are indicated as height and minPts, respectively, in FIG. 2. Through this, semiconductor wafer pattern detection and classification may be performed using a hierarchical clustering method in which a density-based de-noising function of spatial data is added. Clustering generally belongs to the category of unsupervised learning. However, if there is labeled normal/defective used herein, it takes a form of supervised learning using this information to select an optimal tuning parameter.

Once selection of the tuning parameter using learning data is completed, hierarchical clustering is performed on an individual wafer to be tested using a tuned parameter value. In this process, a cluster that does not include at least a predetermined number of individuals may be considered as noise and removed. If the number of individuals belonging to all formed clusters is less than a reference value (minPts) and a corresponding wafer is considered as noise, all the clusters may be removed and there is no cluster in the wafer. That no cluster is formed indicates that no pattern is seen and the corresponding wafer is considered as a normal wafer.

The method of the present invention uses not different values but the same value for each wafer when determining tuning parameter values, based on the fact that wafers have the same size and there is a label. Using this method, it may solve a disadvantage that an amount of time used is proportional to the number of wafers when calculating the number of clusters in wafer failure pattern detection using hierarchical clustering. The aforementioned normal/defective learning process is summarized in the following Algorithm 1 using R function.

[Algorithm 1]
Algorithm 1 Pattern detection algorithm for wafer bin map

| | |
|---|---|
| 1: | INPUT : Failure suspected point on single wafer with cartesian coordinate |
| 2: | OUTPUT : Cluster assigned for each failure suspected point |
| 3: | standard scaling of cartesian coordinates (xᵢ, yᵢ,i = 1,...,n) for each wafer |
| 4: | for each grid : height (hᵢ), minPts (mⱼ) do |
| 5: | for each waferₖ do |
| 6: | dist ← dist (data = (xᵢ, yᵢ,i = 1,...,n), minkowski, p = 3) |
| 7: | model ← hclust(dist, method = single linkage) |
| 8: | cls ← cluster(model, height =hⱼ) |
| 9: | for each clusterᵢ do |
| 10: | if(number of obs. ≤ mⱼ) then un-assign the cluster (de-noise) |
| 11: | end for |
| 12: | if number of cls > 0 then systematic pattern exists |
| 13: | return points' cls for each wafer and grid |
| 14: | end for |
| 15: | end for |
| 16: | Declare whether a wafer is normal or defective. |

In Algorithm 1, i in line 3 represents an i-th observation in a wafer and j in line 4 represents a j-th tuning parameter. hⱼ represents a j-th value of a height parameter and mⱼ represents a j-th tried value in minPts that is the minimum number of individuals to be defined as a cluster. k in line 5 represents a k-th wafer and l in line 9 represents an l-th cluster found in the wafer. A distance is defined in line 6 and hierarchical clustering is performed using the distance in line 7. After saving a formed cluster in line 8, a cluster with fewer individuals than minPts is de-noised in line 10. If at least one cluster is present in line 12 through the above process, a corresponding wafer is determined to be defective. A wafer classified to be normal does not require additional analysis. On the contrary, a wafer determined to be defective requires a process of classifying a pattern of failure. Therefore, the following contents related to classification of a failure pattern may refer to methodology applied only to a wafer determined to be defective.

### 2. Failure Pattern Classification

Wafers determined to be defective in the failure pattern detection process proceed to a task of classifying a pattern of failure in a subsequent stage. For pattern classification, noise needs to be removed first as in the failure pattern detection. Although a de-noising task is already performed in the failure pattern detection process, new learning is attempted without using this because normal wafers are removed and there is a change in data. Therefore, optimal values of tuning parameters are searched by applying Algorithm 1 again using only defective data. In this learning process, various types of defects are labeled. Details of labels related to defects are presented in remaining categories except “none” in FIG. 1.

This second de-noising process differs from the first de-nosing process of the failure pattern detection. Initially, when searching for a tuning parameter, learning needs to be performed to form at least one cluster. If no cluster is formed, a corresponding wafer is considered as a normal wafer so it may be a necessary process. Then, when two or more mixed patterns appear, the numbers of individuals belonging to the respective patterns are compared and remaining patterns are de-noised by reducing to a pattern that includes a largest number of individuals. In reality, two or more mixed patterns sometimes appear. However, considering a case of having two or more labels, the number of possible combinations of patterns significantly increases. Therefore, the present invention is limited to a case in which a single wafer has only a single failure pattern. Similar to the first case, in the second de-noising process, the same tuning parameter selection is applied to all wafers. Through this, a computing time used to calculate the number of clusters for each wafer may be significantly reduced. However, it should be noted that this method is only possible when analyzing data with the same size of dies and wafers as in the present invention.

When the second de-nosing process is completed, only one failure pattern remains. Since learning data includes a label of the failure pattern, a statistical model may be constructed using the label. To this end, a feature of each pattern is extracted and used as a covariate. Further description related thereto is as follows.

Initially, a pattern of a wafer is located in an orthogonal cartesian coordinate system that includes two-dimensional x-axis and y-axis. After centering to locate the center of the wafer at the center, a location of each die is changed to polar coordinates to acquire its radius and angle (Jin et al., 2019). 16 covariates are generated by calculating first to fourth central moments, that is, average, standard deviation, skewness, and kurtosis, using four values (x-axis coordinate, y-axis coordinate, radius, and angle) extractable from two coordinate systems. Also, minimum, maximum, median, and inter quartile range (IQR) of the four values are used to generate 16 covariates. Here, the x-axis coordinate, the y-axis coordinate, the radius, and the angle may represent values for a corresponding die (more specifically, center of the die).

The aforementioned covariates are found through exploratory data analysis and applied and generalized based on a rule. For example, in the case of center failure, the average of x and y needs to be located near 0 and the average over a length of the radius is approximately less than a half of the radius. Since an angle of each distributed point is between 0 and 360°, a dispersion needs to be large. Meanwhile, the edge ring failure has a similar shape to the center failure, but its radius is very large since a defect occurs at the edge of the wafer. The aforementioned 32 covariates may reflect features of such defects to some extents.

Then, first and second eigenvalues of a principal component determined to be able to explain a feature of linear scratch may be used. Also, to verify a feature of curvilinear scratch, a multiple regression model considering a quadratic term of x in Cartesian coordinate system is suitable and a coefficient of determination (R-squared value) of this model is used as a covariate. It can be said that the larger the coefficient of determination (R square) for a y value of a coordinate system, which is a response variable, the better the curvilinear scratch is reflected. In addition, for random failure with a large defective area, the number of dies included in a corresponding pattern may be considered as an additional covariate. According to an example embodiment, it is possible to construct a learning model that classifies a failure pattern by using a total of 36 features as covariates and by using a failure label as a response variable.

Random forest is a supervised learning classifier and has an advantage in that a variable selection is unnecessary. Therefore, failure patterns may be classified using the random forest trained with learning data that includes selected features (covariates) and failure patterns corresponding thereto.

Hereinafter, for comparison to the methodology presented in the present invention, the previously introduced WM-811K data is analyzed.

### 1. Wafer Failure Pattern Detection

A failure pattern is detected by applying the aforementioned hierarchical clustering to actual data. To select a tuning parameter necessary for hierarchical clustering, a grid search is performed by setting a minimum distance (height) at a predetermined intervals (e.g., intervals of 0.2) from 1 to 2 and by setting a minimum allowable number of individuals in a cluster (minPts) at predetermined intervals (e.g., intervals of 2) from 5 to 9. To search for a tuning parameter, data is initially separated into data for training and data for testing. Training data may be configured with a total of six methods from case 1 to case 6 in Table 2. For the training data from case 1 to case 5, four wafers are assigned for each failure pattern and the rest are filled with normal wafers such that sums of the numbers of wafers may become 40, 70, 100, 300, and 500, respectively. Since there are seven failure patterns, the number of normal wafers per case ranges from a minimum of 12 to a maximum of 472. Test data relates to 3,065 wafers, and is the same for all from case 1 to case 6, and a ratio of raw data for each failure pattern is maintained. Therefore, in the case of using case 6 as training data, when the test data is added, it becomes full data shown in Table 1.

TABLE 2

| case | none | center | donut | edgeloc | edgering | loc | random | scratch | total |
|---|---|---|---|---|---|---|---|---|---|
| case 1 | 12 | 4 | 4 | 4 | 4 | 4 | 4 | 4 | 40 |
| case 2 | 42 | 4 | 4 | 4 | 4 | 4 | 4 | 4 | 70 |
| case 3 | 72 | 4 | 4 | 4 | 4 | 4 | 4 | 4 | 100 |
| case 4 | 272 | 4 | 4 | 4 | 4 | 4 | 4 | 4 | 300 |
| case 5 | 472 | 4 | 4 | 4 | 4 | 4 | 4 | 4 | 500 |
| case 6 | 2,767 | 9 | 6 | 195 | 8 | 50 | 6 | 24 | 3,065 |

To compare failure detection performance with the proposed method, spatial filtering using average and median and DBSCAN which is commonly in the industries is exploited. DBSCAN uses R's dbscan package and parameters that require tuning include a maximum radius (epsilon) allowed between a cluster and an individual when generating the cluster and the minimum number of points (minimum point) allowed around the radius to be included. The spatial filtering uses R's raster package and tuning parameters of spatial filtering include a dimension of a filter and a threshold used to determine a pattern.

According to the present invention, learning for semiconductor wafer pattern detection and classification may be performed using only five or less samples for each failure pattern and 100 or more normal samples.

After a tuning parameter selection of each model is completed using training data, each model using this value is applied to a wafer used as test data to predict presence or absence of failure, that is, defect in the wafer. A process of dividing data into data for training and data for testing is repeated ten times and results of predicting presence or absence of failure in the test data for each case are summarized in Table 3.

TABLE 3

| Model | Measure | case 1 | case 2 | case 3 | case 4 | case 5 | case 6 |
|---|---|---|---|---|---|---|---|
| HC | recall | 98.05 (0.54) | 96.44 (0.45) | 95.87 (0.21) | 95.87 (0.21) | 95.87 (0.21) | 96.31 (0.00) |
| | F1 score | 58.49 (2.87) | 67.74 (2.53) | 71.40 (0.20) | 71.40 (0.20) | 71.40 (0.20) | 71.30 (0.00) |
| | accuracy | 85.77 (1.50) | 90.60 (1.32) | 92.53 (0.07) | 92.53 (0.07) | 92.53 (0.07) | 92.46 (0.00) |
| DBSCAN | recall | 95.77 (1.06) | 88.69 (2.01) | 85.27 (1.91) | 68.52 (4.89) | 63.39 (4.14) | 86.58 (0.89) |
| | F1 score | 53.75 (3.39) | 67.23 (2.50) | 69.81 (1.68) | 69.66 (0.86) | 69.46 (0.62) | 73.05 (0.12) |
| | accuracy | 82.23 (2.96) | 91.11 (1.24) | 92.66 (0.78) | 94.29 (0.27) | 94.65 (0.20) | 93.78 (0.10) |
| SF-Ave | recall | 93.52 (1.81) | 86.74 (2.54) | 78.56 (2.92) | 62.65 (1.62) | 60.60 (1.40) | 77.68 (1.79) |
| | F1 score | 55.44 (3.90) | 66.90 (3.12) | 72.05 (0.84) | 72.46 (0.72) | 71.55 (0.78) | 76.02 (0.16) |
| | accuracy | 83.37 (2.97) | 90.78 (1.64) | 94.01 (0.40) | 95.39 (0.07) | 95.33 (0.09) | 95.24 (0.07) |
| SF-Med | recall | 88.05 (4.68) | 70.91 (0.46) | 70.91 (0.46) | 70.91 (0.46) | 70.91 (0.46) | 71.81 (0.00) |
| | F1 score | 47.87 (7.66) | 75.90 (0.39) | 75.90 (0.39) | 75.90 (0.39) | 75.90 (0.39) | 76.16 (0.00) |
| | accuracy | 70.00 (6.98) | 95.62 (0.07) | 95.62 (0.07) | 95.62 (0.07) | 95.62 (0.07) | 95.63 (0.00) |

In Table 3, spatial filtering using average and spatial filtering using median are expressed as SF-Ave and SF-Med, respectively. Resulting values are calculated through 10 times of random splitting and all values are multiplied by 10².

Measures used for evaluation include F1 score, accuracy, and recall, which are defined as TP/(TP+(FP+FN)/2), (TP+TN)/(TP+FP+TN+FN), and TP/(TP+FN), respectively. Here, TP, TN, FP, and FN refer to the numbers of cases corresponding to true positive, true negative, false positive, and false negative, respectively. Among the three measures, recall that is a ratio of detected defects to actual defects is considered most important since it is important to determine a wafer with failure as a defective wafer. Considering that it is a process to find and improve the cause of a problem in a process and ultimately improve yield, this is natural. Therefore, among the results shown in Table 3, it can be said that hierarchical clustering having overall highest recall has the best performance.

In Table 3, a spatial filtering method using median (SF-MED) also shows high accuracy. However, considering the asymmetry that about 90% of data used for analysis relates to normal wafers, the accuracy results are considered only for reference.

Only for case 6 in which a ratio of training data and a ratio of test data are the same, failure detection prediction performance of each pattern is shown in a column indicated with “with” in Table 4. A portion indicated with “without” in Table 4 relates to failure detection prediction performance calculated after excluding samples of a corresponding failure pattern when training data. In this case, prediction performance is calculated without excluding a corresponding pattern from test data. This makes it possible to estimate a performance level of an existing model even when a new failure pattern occurs. A case of scratch failure is notable among the results. Meanwhile, “none” that is a normal wafer is included in training at all times, so does not correspond to “without.” The proposed hierarchical clustering (HC) yields 83.3%, which is significantly higher than other methods, and also exhibits high performance of 90% or more in other patterns. Meanwhile, FP is only 7.8% (=1−92.2%), which is determined to be an allowable level. In contrast, it can be found that other models, particularly, scratch failure, show significantly degraded performance. Another notable phenomenon is that, in the case of DBSCAN, there is a significant difference in prediction power between a case in which training data includes edgeloc and loc patterns and a case in which the training data does not include the same. Therefore, when using a DBSCAN model trained with existing data, if a new pattern not previously observed appears and if the quantity is large, such as edgeloc and loc, performance of determining presence or absence of failure is likely to significantly decrease.

TABLE 4

| | HC | | DBSCAN | | SF-Ave | | SF-Med | |
|---|---|---|---|---|---|---|---|---|
| patterns | with | without | with | without | with | without | with | without |
| center | 94.4 (1.9) | 94.4 (19) | 91.1 (2.8) | 88.9 (2.9) | 83.3 (3.0) | 83.3 (3.0) | 80.0 (4.0) | 80.0 (4.0) |
| donut | 100 (0.0) | 100 (0.0) | 95.0 (2.6) | 100 (0.0) | 100 (0.0) | 100 (0.0) | 100 (0.0) | 100 (0.0) |
| edgeloc | 99.2 (0.2) | 99.2 (0.2) | 89.6 (0.5) | 75.5 (4.5) | 84.6 (0.6) | 73.6 (3.6) | 74.1 (0.6) | 74.1 (0.6) |
| edgering | 100 (0.0) | 100 (0.0) | 91.3 (1.9) | 83.8 (2.7) | 73.8 (3.9) | 70.0 (2.0) | 73.8 (3.9) | 70.0 (2.0) |
| loc | 90.0 (1.2) | 92.0 (2.0) | 85.2 (2.1) | 80.2 (4.4) | 85.0 (1.1) | 83.0 (2.9) | 75.6 (1.1) | 78.0 (1.3) |
| random | 100 (0.0) | 100 (0.0) | 100 (0.0) | 90.0 (5.1) | 100 (0.0) | 100 (0.0) | 100 (0.0) | 100 (0.0) |
| scratch | 83.3 (1.4) | 83.3 (1.4) | 32.1 (2.0) | 20.0 (4.0) | 27.1 (1.4) | 22.1 (2.4) | 16.7 (1.4) | 16.7 (1.4) |
| none | 92.0 (0.1) | NA | 94.9 (0.2) | NA | 96.7 (0.1) | NA | 98.3 (0.0) | NA |

### 2. Wafer Failure Pattern Classification

A wafer determined to be defective in the wafer failure pattern detection is classified into a corresponding failure pattern through a subsequent process. Details related to this process are described above and applied to remaining defective wafer data excluding normal wafers in Table 1. To this end, analysis is performed by randomly dividing a defective wafer into half-and-half, training data and test data. As described above, the classification stage involves the second de-noising and classification process.

To compare the methodology proposed by the present invention in the classification stage, DBSCAN and ordering points to identify the clustering structure (OPTICS) are compared in the second de-nosing stage and then a support vector machine (SVM) and random forest are used in a classification model. Here, the SVM considers two cases, that is, a linear case and a nonlinear case using a radial basis kernel. The OPTICS uses dbscan package, the SVM uses e1071 package, and the random forest uses randomForest package to fit the model. OPTIC is methodology similar to DBSCAN and has three tuning parameters, radius (epsilon), the minimum number of individuals (minPts), and ξ(0<ξ<1) that is a tuning parameter for isolating a high-density pattern. Through previous experiments, the radius is fixed at 10, the minimum number of individuals is searched at intervals of 3 from 3 to 15, and ξ is searched at intervals of 0.03 from 0.01 to 0.5. In the case of the SVM, a tuning parameter, cost, is searched from 2⁻⁵ to 2¹⁰ and gamma of the radial basis kernel is searched at intervals of 0.005 from 0 to 0.05.

Failure pattern classification analysis is evaluated through final classification performance. Evaluation of classification performance uses recall, precision, F1 score, and AUC. Since the number of samples according to a failure type is very unbalanced, accuracy is considered only as a reference level. Standards used to measure the performance is given in Equation 1 and Equation 2. Here, TP and TN represent true positive and true negative, respectively, and FP and FN represent false positive and false negative, respectively. The subscript j denotes a j-th type failure and J denotes a total number of failure types.

$$F 1 = \frac{1}{J} {\sum }_{j = 1}^{N} F {1}_{j} , where \qquad [ Equation 1 ]$$

$$F {1}_{j} = \frac{2 {precision}_{j} \cdot {recall}_{j}}{{precision}_{j} + {recall}_{j}} = \frac{{TP}_{j}}{{TP}_{j} + ( {FP}_{j} + {FN}_{j} ) / 2}$$

$$AUC = \frac{1}{J} {\sum }_{j = 1}^{N} {AUC}_{j} , where \qquad [ Equation 2 ]$$

$${AUC}_{j} = \frac{1}{2} ( \frac{{TP}_{j}}{{TP}_{j} + {FN}_{j}} + \frac{{TN}_{j}}{{TN}_{j} + {TP}_{j}} )$$

The results of prediction for failure types acquired from test data are summarized in Table 5. Initially, it can be seen that the highest prediction power is achieved when de-noising is performed with HC and classification is performed with random forest (RF). Compared to DBSCAN or OPTICS, a de-noising method using HC proposed in the present invention exhibits the overall superior results in light of various evaluation standards. In the case of performing de-noising with OPTICS and performing classification with SVM, some data splitting cases have degraded classification performance, leading to failing in acquiring precision or F1 score and being marked as N/A. This is another example of showing that the performance of OPTICS is inferior.

TABLE 5

| Model | accuracy | precision | recall | F1 score | AUC |
|---|---|---|---|---|---|
| HC + RF | 92.01 (0.44) | 88.14 (0.93) | 80.82 (1.40) | 83.05 (1.16) | 98.75 (0.13) |
| HC + SVM Linear | 87.21 (0.74) | 79.38 (1.55) | 73.69 (1.81) | 74.84 (1.67) | 96.37 (0.33) |
| HC + SVM Radial | 87.45 (0.61) | 81.52 (1.80) | 73.42 (2.05) | 75.32 (1.83) | 96.80 (0.29) |
| DBSCAN + RF | 91.11 (0.52) | 88.28 (0.94) | 75.89 (1.40) | 79.96 (1.22) | 98.03 (0.26) |
| DBSCAN + SVM Linear | 86.14 (0.38) | 80.86 (1.20) | 68.06 (1.28) | 70.87 (1.23) | 95.62 (0.24) |
| DBSCAN + SVM Radial | 87.21 (0.61) | 83.19 (1.58) | 68.99 (1.22) | 72.82 (1.20) | 96.52 (0.28) |
| OPTICS + RF | 87.69 (0.41) | 90.72 (0.98) | 65.47 (1.20) | 73.69 (1.19) | 96.44 (0.47) |
| OPTICS + SVM Linear | 78.49 (1.00) | N/A | 42.96 (2.95) | N/A | 89.06 (0.33) |
| OPTICS + SVM Radial | 79.48 (0.74) | N/A | 41.40 (2.10) | N/A | 90.70 (0.44) |

In Table 5, the results are calculated through 10 times of random splitting and all values are multiplied by 10².

Referring to classification performance for each class in Table 6, when using RF, HC shows F1 score of 80 or more for all except donut failure (donut) and shows AUC of 98.00% or more for all except local failure (local) of 97.21%. Compared to this, DBSCAN also exhibits excellent performance, but has three F1 scores below 80, which shows some deviation compared to HC. A confusion matrix calculated as a percentage using the results of HC+RF showing the best performance in Table 5 is shown in Table 7. The results are acquired by averaging 10 values.

It can be seen that classification performance is poor in a few classes, such as donut failure, including less than 10 pieces of data among data used for failure classification.

TABLE 6

| Pattern | Method | precision | | recall | | F1 score | AUC |
|---|---|---|---|---|---|---|---|
| center | HC | 93.53 | (1.78) | 91.11 | (2.77) | 92.01 (1.59) | 99.15 (0.39) |
| | DBSCAN | 91.36 | (2.15) | 100 | (0.00) | 95.37 (1.17) | 99.98 (0.01) |
| | OPTICS | 93.39 | (2.21) | 72.22 | (2.48) | 81.10 (1.82) | 98.72 (0.56) |
| donut | HC | 90.14 | (4.26) | 65.00 | (4.61) | 73.72 (2.76) | 99.24 (0.15) |
| | DBSCAN | 95.83 | (2.85) | 55.00 | (5.00) | 68.42 (3.59) | 99.39 (0.22) |
| | OPTICS | 100 | (0.00) | 52.00 | (3.59) | 67.82 (2.85) | 98.61 (0.22) |
| loc | HC | 84.75 | (1.34) | 84.00 | (1.91) | 84.20 (1.13) | 97.21 (0.32) |
| | DBSCAN | 82.62 | (0.80) | 86.80 | (1.50) | 84.56 (0.70) | 97.49 (0.32) |
| | OPTICS | 74.77 | (0.78) | 80.49 | (1.19) | 77.50 (0.88) | 96.27 (0.36) |
| edgeloc | HC | 94.96 | (0.42) | 98.05 | (0.30) | 96.47 (0.22) | 98.63 (0.19) |
| | DBSCAN | 95.77 | (0.42) | 98.21 | (0.29) | 96.96 (0.21) | 98.64 (0.24) |
| | OPTICS | 91.45 | (0.38) | 97.61 | (0.36) | 94.43 (0.31) | 97.23 (0.32) |
| edgering | HC | 92.56 | (3.53) | 73.75 | (2.92) | 81.36 (2.10) | 99.30 (0.17) |
| | DBSCAN | 83.71 | (4.02) | 65.00 | (4.49) | 72.33 (3.45) | 95.72 (1.05) |
| | OPTICS | 91.39 | (4.87) | 56.25 | (5.67) | 67.01 (4.51) | 96.98 (0.55) |
| random | HC | 76.43 | (5.84) | 93.33 | (3.69) | 82.35 (3.69) | 99.94 (0.03) |
| | DBSCAN | 71.67 | (4.10) | 80.00 | (4.84) | 75.12 (4.05) | 99.12 (0.23) |
| | OPTICS | 96.00 | (4.00) | 48.00 | (4.10) | 62.62 (4.24) | 89.01 (3.02) |
| scratch | HC | 94.99 | (1.67) | 76.25 | (1.87) | 84.47 (1.52) | 98.43 (0.43) |
| | DBSCAN | 91.75 | (1.62) | 72.08 | (2.24) | 80.53 (1.55) | 98.72 (0.20) |
| | OPTICS | 85.59 | (2.74) | 62.08 | (2.28) | 71.73 (2.03) | 96.42 (0.62) |

In Table 6, resulting values are calculated through ten times of random splitting and all values are multiplied by 10².

TABLE 7

| Reference | center | donut | loc | edgeloc | edgering | random | scratch |
|---|---|---|---|---|---|---|---|
| center | 91.11 | 1.11 | 4.44 | 3.33 | 0 | 0 | 0 |
| donut | 5.00 | 65.00 | 20.00 | 1.67 | 0 | 8.33 | 0 |
| loc | 0.60 | 0.40 | 84.00 | 13.00 | 0 | 0.40 | 1.60 |
| edgeloc | 0 | 0 | 0.97 | 98.05 | 0.31 | 0.56 | 0.10 |
| edgering | 0 | 0 | 0 | 26.25 | 73.75 | 0 | 0 |
| random | 0 | 5.00 | 0 | 1.67 | 0 | 93.33 | 0 |
| scratch | 0 | 0 | 17.50 | 4.58 | 0 | 1.67 | 76.25 |

In Table 7, resulting values are calculated through 10 times of random splitting.

In the foregoing, hierarchical clustering is proposed for failure pattern detection and classification of a semiconductor wafer. The conventional hierarchical clustering method used for failure classification may be expanded and used for failure detection and the performance of failure pattern detection is proved to be superior to competing methods through experiments using real-world wafer bin map data.

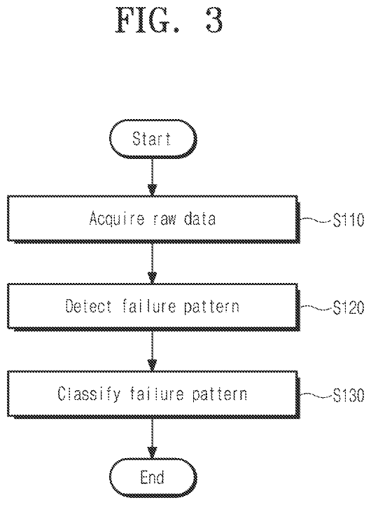

FIG. 3 is a flowchart illustrating a method of performing semiconductor wafer pattern detection and/or classification using hierarchical clustering according to an example embodiment of the present invention.

Referring to FIG. 3, the proposed method may be performed by a computing device including at least a processor and/or a memory. That is, at least some of operations included in the proposed method may be understood as an operation of the processor included in the computing device and the computing device may also be referred to as a device that performs semiconductor wafer pattern detection and classification. The computing device may include, for example, a personal computer (PC), a server, a laptop computer, a tablet PC, and the like, and may be implemented as physically separated at least one device. In the following, in describing the proposed method, detailed descriptions of contents that overlap the aforementioned description will be omitted.

In operation S110, raw data is acquired. The raw data may include a wafer bin map (WBM). For example, the raw data may include a wafer bin map (WBM), such as WM-811K data. The raw data may be received from a server or an external device that provides the raw data through a predetermined wired/wireless communication network, may be received from a storage device such as a USB memory device through a predetermined input/output (I/O) interface, or may be prestored in the computing device. Depending an example embodiment, target data may be further received with the raw data or separate from the raw data. The target data refers to data related to a target wafer that is a subject of failure pattern detection and/or failure pattern classification and may include point information that includes information on presence or absence of failure present on a wafer. The point information may include information on an observation in a geographical space, that is, presence or absence of failure on a wafer and location information of a point. Depending on example embodiments, the target data may represent a wafer bin map (WBM) of the target wafer.

In operation S120, a failure pattern is detected. Through this, whether the target wafer is defective may be determined. That is, whether a failure pattern is present in the target wafer may be determined.

Initially, a first tuning parameter for hierarchical clustering (HC) needs to be determined. The first tuning parameter may include a height that represents a minimum allowable distance and the minimum number of individuals in a cluster (minPts). The first tuning parameter may be determined using the raw data. In detail, a value of the first tuning parameter for hierarchical clustering (HC) may be determined through grid search using at least a portion of the raw data. Here, target data and data used for the grid search may be data related to wafers having the same size. Also, when the first tuning parameter for the hierarchical clustering (HC) is predetermined, a separate operation of determining the first tuning parameter may be omitted. Depending on example embodiments, determining of the first tuning parameter may be performed at any point in time before or after performing operation S110.

A de-noising operation through hierarchical clustering (HC) is performed using the determined first tuning parameter. That is, a cluster that does not satisfy the first tuning parameter is removed by performing the hierarchical clustering (HC).

If a systematic pattern (i.e., failure pattern) is absent as a result of de-noising, the target wafer may be determined as a normal wafer. On the contrary, if the systematic pattern (i.e., failure pattern) is present, the target wafer is determined as an abnormal (defective) wafer and a subsequent failure pattern classification operation may be performed.

In operation S130, a failure pattern of the target wafer is classified. That is, the failure pattern included in the wafer determined (or decided) to be defective may be classified.

Initially, a second tuning parameter for hierarchical clustering (HC) needs to be determined. The second tuning parameter may include a height that represents a minimum allowable distance and the minimum number of individuals in a cluster (minPts). The second tuning parameter may be determined using the raw data. In detail, a value of the second tuning parameter for hierarchical clustering (HC) may be determined through grid search using at least a portion of the raw data. Here, target data and data used for the grid search may be data related to wafers having the same size. Also, when the second tuning parameter for the hierarchical clustering (HC) is predetermined, a separate operation of determining the second tuning parameter may be omitted. Depending on example embodiments, determining of the second tuning parameter may be performed at any point in time before or after performing operation S110. Also, since the second tuning parameter is determined using only abnormal data among the raw data, the second tunning parameter may have a value different from that of the first tuning parameter.

A de-noising operation through hierarchical clustering (HC) and/or failure pattern isolation operation is performed using the determined second tuning parameter. That is, a cluster that does not satisfy the second tuning parameter is removed by performing hierarchical clustering (HC). Also, if a plurality of failure patterns is present in the target wafer in a hierarchical clustering (HC) process, only a representative failure pattern may be maintained and remaining failure patterns may be removed.

A feature for failure pattern classification may be extracted and a failure pattern may be classified using the extracted feature. This operation may be performed for each failure pattern. Also, the extracted feature may represent the aforementioned covariate and classification of the failure pattern may be performed using a pretrained classification model (e.g., random forest model).

As described above, it is possible to verify cause of failure in a manufacturing process and take an action by determining whether a target wafer is defective and by using classification results for a failure pattern.

The aforementioned method according to example embodiments may be implemented in a form of a program executable by a computer apparatus. Here, the program may include, alone or in combination, a program instruction, a data file, and a data structure. The program may be specially designed to implement the aforementioned method or may be implemented using various types of functions or definitions known to those skilled in the computer software art and thereby available. Also, here, the computer apparatus may be implemented by including a processor or a memory that enables a function of the program and, if necessary, may further include a communication apparatus.

The program for implementing the aforementioned method may be recorded in computer-readable record media. The media may include, for example, a semiconductor storage device such as an SSD, ROM, RAM, and a flash memory, magnetic disk storage media such as a hard disk and a floppy disk, optical record media such as disc storage media, a CD, and a DVD, magneto optical record media such as a floptical disk, and at least one type of physical device capable of storing a specific program executed according to a call of a computer such as a magnetic tape.

Although some example embodiments of an apparatus and method are described, the apparatus and method are not limited to the aforementioned example embodiments. Various apparatuses or methods implementable in such a manner that one of ordinary skill in the art makes modifications and alterations based on the aforementioned example embodiments may be an example of the aforementioned apparatus and method. For example, although the aforementioned techniques are performed in order different from that of the described methods and/or components such as the described system, architecture, device, or circuit may be connected or combined to be different form the above-described methods, or may be replaced or supplemented by other components or their equivalents, it still may be an example embodiment of the apparatus and method.

The device described above can be implemented as hardware elements, software elements, and/or a combination of hardware elements and software elements. For example, the device and elements described with reference to the embodiments above can be implemented by using one or more general-purpose computer or designated computer, examples of which include a processor, a controller, an ALU (arithmetic logic unit), a digital signal processor, a microcomputer, an FPGA (field programmable gate array), a PLU (programmable logic unit), a microprocessor, and any other device capable of executing and responding to instructions. A processing device can be used to execute an operating system (OS) and one or more software applications that operate on the said operating system. Also, the processing device can access, store, manipulate, process, and generate data in response to the execution of software. Although there are instances in which the description refers to a single processing device for the sake of easier understanding, it should be obvious to the person having ordinary skill in the relevant field of art that the processing device can include a multiple number of processing elements and/or multiple types of processing elements. In certain examples, a processing device can include a multiple number of processors or a single processor and a controller. Other processing configurations are also possible, such as parallel processors and the like.

The software can include a computer program, code, instructions, or a combination of one or more of the above and can configure a processing device or instruct a processing device in an independent or collective manner. The software and/or data can be tangibly embodied permanently or temporarily as a certain type of machine, component, physical equipment, virtual equipment, computer storage medium or device, or a transmitted signal wave, to be interpreted by a processing device or to provide instructions or data to a processing device. The software can be distributed over a computer system that is connected via a network, to be stored or executed in a distributed manner. The software and data can be stored in one or more computer-readable recorded medium.

A method according to an embodiment of the invention can be implemented in the form of program instructions that may be performed using various computer means and can be recorded in a computer-readable medium. Such a computer-readable medium can include program instructions, data files, data structures, etc., alone or in combination. The program instructions recorded on the medium can be designed and configured specifically for the present invention or can be a type of medium known to and used by the skilled person in the field of computer software. Examples of a computer-readable medium may include magnetic media such as hard disks, floppy disks, magnetic tapes, etc., optical media such as CD-ROM's, DVD's, etc., magneto-optical media such as floptical disks, etc., and hardware devices such as ROM, RAM, flash memory, etc., specially designed to store and execute program instructions. Examples of the program instructions may include not only machine language codes produced by a compiler but also high-level language codes that can be executed by a computer through the use of an interpreter, etc. The hardware mentioned above can be made to operate as one or more software modules that perform the actions of the embodiments of the invention and vice versa.

While the present invention is described above referencing a limited number of embodiments and drawings, those having ordinary skill in the relevant field of art would understand that various modifications and alterations can be derived from the descriptions set forth above. For example, similarly adequate results can be achieved even if the techniques described above are performed in an order different from that disclosed, and/or if the elements of the system, structure, device, circuit, etc., are coupled or combined in a form different from that disclosed or are replaced or substituted by other elements or equivalents. Therefore, various other implementations, various other embodiments, and equivalents of the invention disclosed in the claims are encompassed by the scope of claims set forth below.

What is claimed is:

1. A method for semiconductor wafer pattern detection and classification using hierarchical clustering (HC), performed by a computing device comprising at least a processor, the method comprising:
acquiring raw data;
detecting a failure pattern of a target semiconductor wafer; and
classifying the failure pattern of the target semiconductor wafer,
wherein the detecting of the failure pattern comprises:
removing a cluster that does not satisfy a first tuning parameter through the hierarchical clustering (HC); and
determining that the target semiconductor wafer is normal when the cluster that satisfies the first tuning parameter is absent.

2. The method of claim 1, wherein the first tuning parameter includes a first height that represents a first minimum allowable distance between clusters and a first minimum number of individuals in a cluster (minPts) to use a hierarchical clustering method in which a density-based de-noising function of spatial data is added.

3. The method of claim 1, wherein the hierarchical clustering (HC) uses a single linkage and a Minkowski (p=3) distance for density-based cluster construction.

4. The method of claim 1, wherein the classifying of the failure pattern comprises:
removing a cluster that does not satisfy a second tuning parameter through the hierarchical clustering (HC) and isolating the cluster into a meaningful individual pattern through the second tuning parameter;
extracting a feature of a cluster that satisfies the second tuning parameter; and
classifying the failure pattern using a pretrained random forest model based on the feature.

5. The method of claim 4, wherein the second tuning parameter includes a second height that represents a second minimum allowable distance and a second minimum number of individuals in a cluster (minPts).

6. The method of claim 2, wherein the raw data includes the same size of wafer bin maps (WBMs), and
in the case of the first tuning parameter and the second tuning parameter, a single tuning parameter is determined for all wafers through grid search using at least a portion of the raw data.

7. The method of claim 6, wherein the second tuning parameter is determined using at least a portion of abnormal data among the raw data.

8. The method of claim 6, wherein the first tuning parameter uses evaluation metrics in order of F1 score, accuracy, recall, and precision for a defect status, and
the second tuning parameter uses evaluation metrics in order of F1 macro, Recall macro, and Kappa that are pattern classification performance after performing all of pattern isolation, feature extraction, and classification analysis.

9. The method of claim 5, wherein the raw data includes the same size of wafer bin maps (WBMs), and
in the case of the first tuning parameter and the second tuning parameter, a single tuning parameter is determined for all wafers through grid search using at least a portion of the raw data.

10. The method of claim 1, wherein the method for semiconductor wafer pattern detection and classification learns a failure detection status using five or less samples for each failure pattern and 100 or more normal samples.

11. The method of claim 4, wherein the method for semiconductor wafer pattern detection and classification uses an orthogonal and polar coordinate system in a two-dimensional space to quantify a feature of a single wafer pattern and uses the same for failure classification learning and prediction by including a feature that uses statistics related to average, standard deviation, skewness, and kurtosis.

12. The method of claim 4, wherein the method for semiconductor wafer pattern detection and classification includes first and second eigenvalues of a principal component analysis (PCA) for a linear scratch pattern and includes an R-squared value after fitting a multiple regression model that considers a quadratic term of an orthogonal coordinate system x for a curvilinear scratch pattern to quantity a scratch pattern among features of a single wafer pattern, and uses the same for failure classification learning and prediction.
